(19) United States
(12) Patent Application Publication
(10) Pub. No.: US 2013/0193400 A1
(43) Pub. Date: Aug. 1, 2013

(54) Memory Cell Structures and Memory Arrays

(71) Applicants: Gurtej S. Sandhu, Boise, ID (US); John K. Zahurak, Eagle, ID (US)

(72) Inventors: Gurtej S. Sandhu, Boise, ID (US); John K. Zahurak, Eagle, ID (US)

(73) Assignee: MICRON TECHNOLOGY, INC., Boise, ID (US)

(21) Appl. No.: 13/359,715

(22) Filed: Jan. 27, 2012

(51) Int. Cl. H01L 45/00

(52) U.S. Cl. 257/5; 257/2; 257/E45.003

(57) ABSTRACT

Some embodiments include memory cell structures. The structures include a vertical transistor having a bottom source/drain region electrically coupled to a first access/sense line, and having a gate comprised by a second access/sense line. The structures also include programmable material over the vertical transistor and electrically coupled with a top source/drain region of the vertical transistor, with the programmable material having at least two compositionally different regions. The structures also include an electrically conductive material over and directly against the programmable material. Some embodiments include memory arrays.

### TECHNICAL FIELD

Memory cell structures and memory arrays.

### BACKGROUND

Memory is one type of integrated circuitry, and is used in computer systems for storing data. Integrated memory is usually fabricated in one or more arrays of individual memory cells. The memory cells are configured to retain or store memory in at least two different selectable states. In a binary system, the states are considered as either a “0” or a “1”. In other systems, at least some individual memory cells may be configured to store more than two levels or states of information.

One type of memory is dynamic random access memory (DRAM). DRAM generally has fast read/write characteristics as compared to other memory types. However, DRAM is also relatively volatile—and thus requires refresh to maintain data integrity.

It is desired to develop improved DRAM cell architectures, and improved memory arrays incorporating such architectures. For instance, it is desired to develop DRAM cells having fast read/write characteristics, but with improved data retention in order to reduce power consumption attributed to refresh.

### BRIEF DESCRIPTION OF THE DRAWINGS

FIG. 1 is a diagrammatic, cross-sectional view of an example embodiment memory structure.

FIG. 2 is a diagrammatic, three-dimensional view of an example embodiment memory array.

FIGS. 3-5 are a diagrammatic top view and diagrammatic cross-sectional side views of an example embodiment memory array analogous to that of FIG. 2. The view of FIG. 4 is along the lines 4-4 of FIGS. 3 and 5; and the view of FIG. 5 is along the lines 5-5 of FIGS. 3 and 4.

FIGS. 6-8 are a diagrammatic top view and diagrammatic cross-sectional side views of another example embodiment memory array. The view of FIG. 7 is along the lines 7-7 of FIGS. 6 and 8; and the view of FIG. 8 is along the lines 8-8 of FIGS. 6 and 7.

### DETAILED DESCRIPTION OF THE ILLUSTRATED EMBODIMENTS

A conventional DRAM cell may include a capacitor utilized in combination with a transistor. The transistor may function as a select device for controlling electrical flow to and from the capacitor. The capacitor may have two distinguishable conditions corresponding to whether charge is stored on the capacitor or not. Thus, the DRAM cell may have a first memory state corresponding to a first charge storage condition of the capacitor, and may have a second memory state corresponding to a second charge storage condition of the capacitor.

In some embodiments, the invention includes DRAM cell architectures in which structures containing programmable material are utilized instead of the capacitor of conventional DRAM. In some embodiments, the programmable material comprises at least two compositionally different regions. Such compositionally different regions of the programmable material may correspond to, for example, multivalent oxide and high-k dielectric.

It is difficult to scale the capacitors of conventional DRAM cells into increasingly tighter dimensions associated with increasing integration densities. The replacement of capacitors with the structures described herein may overcome such difficulties. Also, replacement of capacitors of conventional DRAM cells with the structures described herein may improve data retention, leading to less-frequent refresh. If refresh is less frequent, there can be a corresponding improvement in power utilization. Such can lead to better battery life of battery-dependent devices.

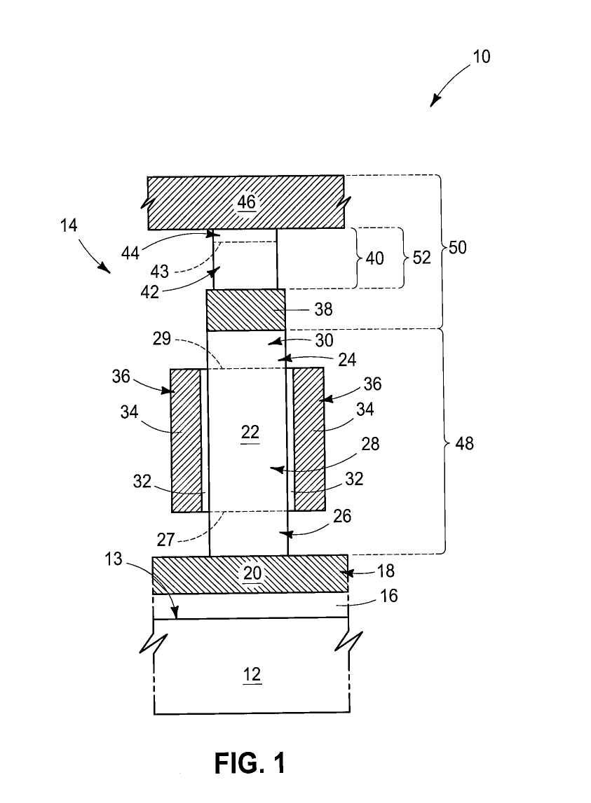

Example memory cell architectures and memory arrays are described below with reference to FIGS. 1-8.

Referring to FIG. 1, a memory cell structure 14 is illustrated as part of a semiconductor construction 10.

The semiconductor construction includes a base 12 supporting the structure 14. Base 12 may comprise, consist essentially of, or consist of monocrystalline silicon, and may be referred to as a semiconductor substrate, or as a portion of a semiconductor substrate. The terms “semiconductive substrate,” “semiconductor construction” and “semiconductor substrate” mean any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductive substrates described above. Although base 12 is shown to be homogenous, the base may comprise numerous materials in some embodiments. For instance, base 12 may correspond to a semiconductor substrate containing one or more materials associated with integrated circuit fabrication. In such embodiments, such materials may correspond to one or more of refractory metal materials, barrier materials, diffusion materials, insulator materials, etc.

A dielectric material 16 is over base 12, and a first access/sense line 18 is over the dielectric material.

The dielectric material 16 may comprise any suitable composition or combination of compositions; and in some embodiments may comprise, consist essentially of, or consist of one or both of silicon dioxide and silicon nitride.

The access/sense line 18 may be, for example, a bitline or wordline. The line 18 comprises an electrically conductive material 20. Such material may comprise any suitable electrically conductive composition or combination of compositions; and in some embodiments may comprise, consist essentially of, or consist of one or more of various metals (e.g., tungsten, titanium, aluminum, etc.), metal-containing compounds (e.g., metal silicide, metal carbide, metal nitride, etc.) and conductively-doped semiconductor materials (e.g., conductively-doped silicon, conductively-doped germanium, etc.).

A semiconductor material 22 is over the access/sense line 18, and forms a vertical pedestal 24. The pedestal is referred to as being “vertical” in that it extends vertically relative to a horizontal upper surface 13 of base 12. Unless explicitly indicated otherwise, the term “vertical” means primarily vertical, and thus encompasses orientations which are substantially vertical as well as orientations which are absolutely vertical.

The semiconductor material 22 may comprise any suitable composition or combination of compositions; and in some embodiments may comprise, consist essentially of, or consist of one or both of silicon and germanium.

The semiconductor material 22 is doped so that such semiconductor material is subdivided into a bottom source/drain region 26, a top source/drain region 30, and a channel region 28 between the top and bottom source/drain regions. Dashed lines 27 and 29 are provided to diagrammatically illustrate boundaries between the channel region and the bottom and top source/drain regions, respectively. Any suitable dopants may be utilized to form the regions 26, 28 and 30; including any of various n-type and/or p-type dopants (e.g., phosphorus, boron, etc.).

The bottom source/drain region 26 is electrically coupled to the first access/sense line 18. In the shown embodiment, the bottom source/drain region directly contacts the access/sense line 18. In other embodiments, the bottom source/drain region may be electrically coupled to the access/sense line 18 through one or more electrically conductive materials (not shown). For instance, an electrically conductive material (such as a metal silicide) may be provided between the access/sense line 18 and the bottom source/drain region 26 to improve adhesion and/or electrical coupling of the bottom source/drain region to the access/sense line 18.

Dielectric material 32 is provided along sidewalls of the semiconductor material pedestal 24; and specifically along and directly against the channel region 28 in the shown embodiment. The dielectric material 32 may comprise any suitable composition or combination of compositions; and in some embodiments may comprise, consist essentially of or consist of silicon dioxide. The dielectric material 32 may be referred to as gate dielectric in some embodiments. Although the dielectric material 32 is shown only extending along channel region 28 in the shown embodiment, in other embodiments the dielectric material may also extend along one or both of the source/drain regions 26 and 30. Also, although the dielectric material 32 is shown extending entirely along the channel region 28 in the shown embodiment, in other embodiments the dielectric material may extend along only a portion of the length of the channel region.

Electrically conductive material 34 is provided along and directly against the dielectric material 32. The electrically conductive material 34 may be referred to as gate material in some embodiments. Material 34 may comprise any suitable composition or combination of compositions; and in some embodiments may comprise, consist essentially of, or consist of one or more of various metals, metal-containing compounds, and conductively-doped semiconductor materials. The electrically conductive material 34 may be comprised by a second access/sense line 36 (for instance, a wordline or bitline).

An electrically conductive material 38 is over the top source/drain region 30, and programmable material 40 is over such electrically conductive material. The electrically conductive material 38 may be utilized to improve the adhesion and/or electrical coupling between the source/drain region 30 and the programmable material 40, and may comprise any suitable composition. In some embodiments, the electrically conductive material 38 may comprise, consist essentially of, or consist of metal silicide (for instance, titanium silicide) and/or metal carbide. In some embodiments (not shown) the electrically conductive material 38 may be omitted. The programmable material 40 is electrically coupled to the top source/drain region 30 through the conductive material 38 in the shown embodiment; and in other embodiments may be electrically coupled to such top source/drain region by being in direct contact with the top source/drain region or may be connected through Schottky barrier materials.

The programmable material 40 comprises at least two compositionally different regions, and in the shown embodiment comprises the regions 42 and 44. A dashed line 43 is provided to diagrammatically illustrate a boundary between the regions 42 and 44. In some embodiments, one of the regions 42 and 44 may comprise, consist essentially of, or consist of multivalent metal oxide; and the other may comprise, consist essentially of, or consist of an electrically insulative material, such as a high-k dielectric material. The regions 42 and 44 may have the same thickness as one another, or different thicknesses. The relative thicknesses of the regions 42 and 44 may be adjusted to achieve desired performance characteristics of a memory structure.

The multivalent metal oxide may comprise any suitable composition; and in some embodiments may comprise a composition containing oxygen in combination with one or more of praseodymium, barium, calcium, manganese, strontium, titanium, iron, cesium and lead. For instance, the multivalent metal oxide may comprise, consist essentially of, or consist of calcium manganese oxide doped with one or more of Pr, La, Sr and Sm. In some embodiments, the multivalent metal oxide may comprise a combination of Pr, Ca, Mn and O; and, for example, may correspond to a material referred to as PCMO by persons of ordinary skill in the art.

The region of programmable material 40 which is adjacent the multivalent metal oxide region may comprise any suitable composition or combination of compositions, and in some embodiments may comprise, consist essentially of, or consist of one or more high-k oxides. Examples of suitable high-k dielectric materials are compositions which comprise, consist essentially of, or consist of oxides containing one or more of hafnium, zirconium, yttrium, and aluminum. In some example embodiments, suitable high-k dielectric materials may comprise, consist essentially of, or consist of yttrium-doped zirconium oxide (YZO).

An electrically conductive material 46 is over the programmable material 40 and electrically coupled to the programmable material (the material 46 may be ohmically connected to the material 40 in some embodiments, and may be connected to the material 40 through Schottky barrier materials in some embodiments). In the shown embodiment, the electrically conductive material 46 is directly against the upper region 44 of the programmable material. In some example embodiments, such upper region may correspond to multivalent metal oxide. In other example embodiments, such upper region may correspond to high-k dielectric material.

The electrically conductive material 46 may comprise any suitable composition or combination of compositions; and in some embodiments may comprise, consist essentially of, or consist of one or more of various metals, metal-containing compounds, and conductively-doped semiconductor materials.

The memory structure 14 comprises a vertical transistor 48 in combination with a data-retaining structure 50. Specifically, the semiconductor material 22, together with gate dielectric 32 and electrically conductive gate material 34 forms the vertical transistor 48; and the electrically conductive materials 38 and 46, together with the programmable material 40, form the data-retaining structure 50.

The data-retaining structure 50 may function analogously to resistive memory or memristors. However, unlike conventional applications for resistive memory in which such memory is incorporated into RRAM, the present application incorporates the memory into a DRAM. Specifically, both of the access/sense lines 18 and 36 are on the same side of the programmable material 40 as one another, rather than being on opposing sides of the programmable material from one another as would occur in an RRAM. The incorporation of the resistive memory into a DRAM may enable fabrication of memory arrays having lower cost per bit than analogous memory arrays in which the resistive memory is incorporated into RRAM.

In some embodiments, the data-retaining structure 50 may be considered to substitute for a capacitor of a conventional DRAM cell. The data-retaining structure 50 may have better retention than a capacitor, so that refresh may be conducted at intervals measured in seconds, minutes, hours, days or even longer; as compared to the refresh intervals of milliseconds (or shorter) associated with conventional DRAM. Also, the data-retaining structure 50 may be easier to scale for higher levels of integration than the capacitors of conventional DRAM.

In some embodiments, the data-retaining structure may be considered to comprise a data-retaining cell 52 (which may be alternatively referred to as a programmable volume) corresponding to the programmable material 40.

The memory structure 14 may be operated under any suitable programming conditions. For instance, the upper conductive material 46 may be part of a conductive plate held at V_{cc}/2, and the access/sense line 18 may be operated at voltages from 0 to V_{cc} for write and erase operations so that the programmable material 40 is exposed to forward and reverse field. A V_{cc} of about 5 volts may provide a sufficient read margin and retention time under some conditions. The memory structure may support fast read of a random bit, and may have endurance of at least about 1×10⁷ cycles. The write and erase times of the memory structure may be about 1 microsecond in some embodiments.

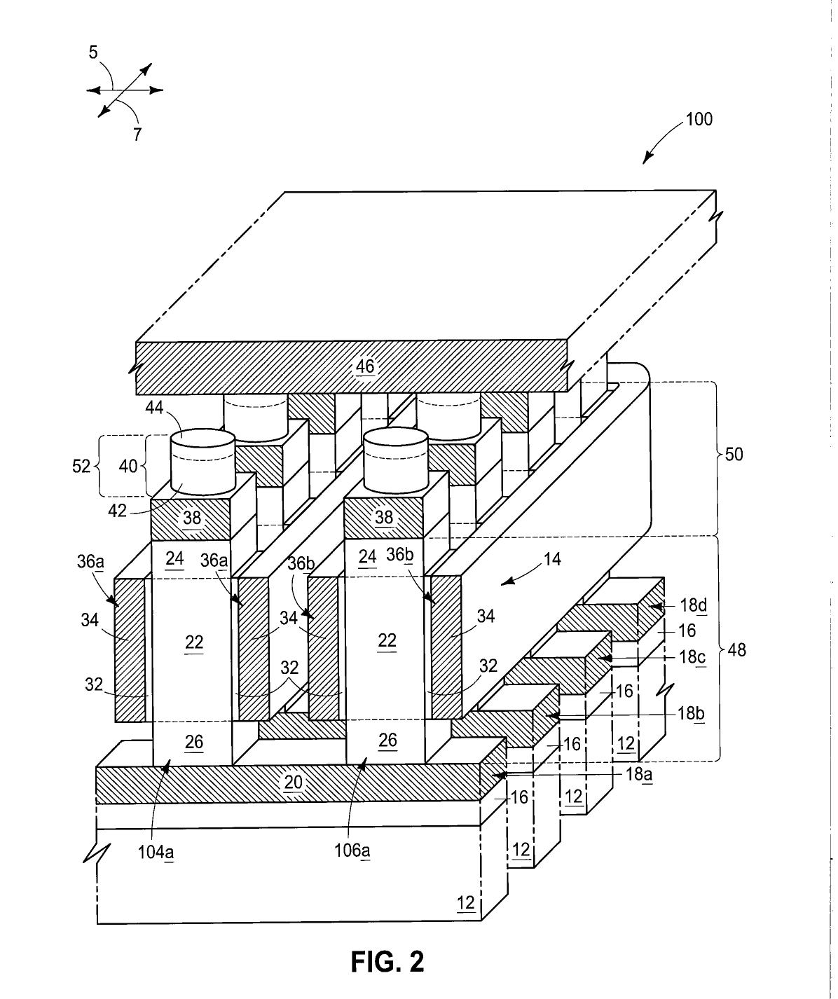

The memory structure 14 may be incorporated into a memory array. FIG. 2 shows a three-dimensional view of an example embodiment memory array 100. Identical numbering will be utilized to describe the memory array of FIG. 2 as is used above to describe the construction of FIG. 1, where appropriate. The memory array comprises a plurality of first access/sense lines (18a, 18b, 18c and 18d) extending along a first direction, with the first direction being along an illustrated axis 5. The memory array comprises a plurality of memory structures 14 (only one of which is labeled); and comprises a plurality of second access/sense lines 36a and 36b extending along a second direction, with the second direction being along an illustrated axis 7. The second direction intersects the first direction (as illustrated by axis 7 intersecting axis 5), and in the shown embodiment is substantially orthogonal to the first direction.

In some embodiments, the access/sense lines 18a, 18b, 18c and 18d may be considered to be representative of a first series of access/sense lines, and the access/sense lines 36a and 36b may be considered to be representative of a second series of access/sense lines.

The access/sense lines 36a and 36b form gates along the vertical transistors of the memory structures 14. In the illustrated embodiment, the gate material is on two sides of the channel regions. In other embodiments, the gate material may entirely surround the channel regions, or may be in other configurations.

The memory structures 14 comprise the data-retaining cells 52 (only one of which is labeled) in combination with the vertical transistors 48 (only one of which is labeled).

In the shown embodiment, the electrically conductive material 46 forms a plate of substantially uniform thickness that is entirely over the programmable material 40, and which extends over all of the data-retaining cells 52 (a region of the plate is broken-away in the view of FIG. 2 to enable better illustration of some of the memory structures).

In some embodiments, the memory array may be considered to comprise rows of memory structures 14 along the axis 5 (i.e., the rows may extend along the access/sense lines 18a-d), and columns of the memory structures along the axis 7 (i.e., the columns may extend along the access/sense lines 36a and 36b). The plate of conductive material 46 may be comprised by multiple plate structures, rather than the shown single plate structure; and each plate structure may extend across two or more adjacent data-retaining cells 52 along a row, and across two or more adjacent data-retaining cells 52 along a column. Such aspect may further distinguish some embodiments of the present invention from RRAM applications utilizing materials analogous to the programmable material 40, in that RRAM applications would generally not have a conductive material coupling adjacent memory cells along both the rows and columns of a memory array. Specifically, conductive material adjacent the programmable material of an RRAM application is an electrode, and it would generally not be desired to short adjacent electrodes across the rows and columns of an RRAM array. In contrast, the conductive material 46 of FIG. 2 is a conductive plate extending across multiple data-retaining structures in adjacent rows and columns of the illustrated DRAM array. The utilization of the terms “row” and “column” is to assist in explaining aspects of the invention. It is recognized that the prior art has conventions as to the directions of the rows and columns in various memory arrays (for instance, rows of DRAM arrays may be conventionally understood to be along wordlines). The terms “row” and “column” as used herein may or may not correspond to conventional uses of such terms in the prior art descriptions of memory arrays.

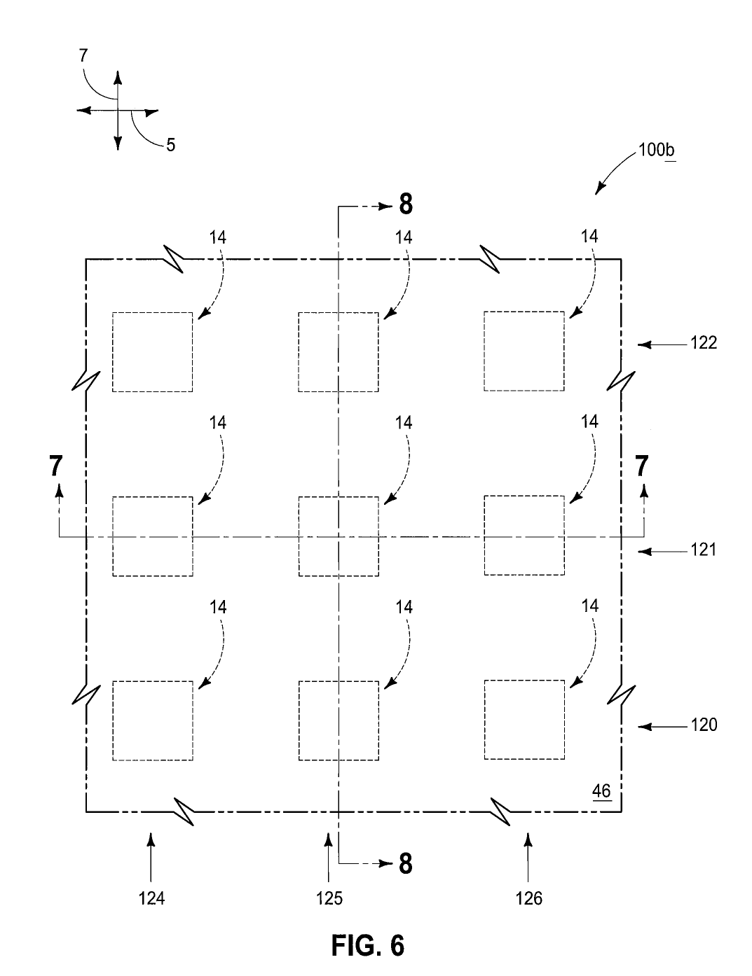

The embodiment of FIG. 2 illustrates programmable material 40 as a cylinder extending between conductive material 38 and the plate of conductive material 46. In other embodiments, the programmable material may have other configurations. Further, although the programmable material 40 is illustrated to be singulated so that the programmable material forms structures that are in one-to-one correspondence with memory cells, in other embodiments (discussed below with reference to FIGS. 6-8) the programmable material may be formed as a continuous expanse across multiple memory cells.

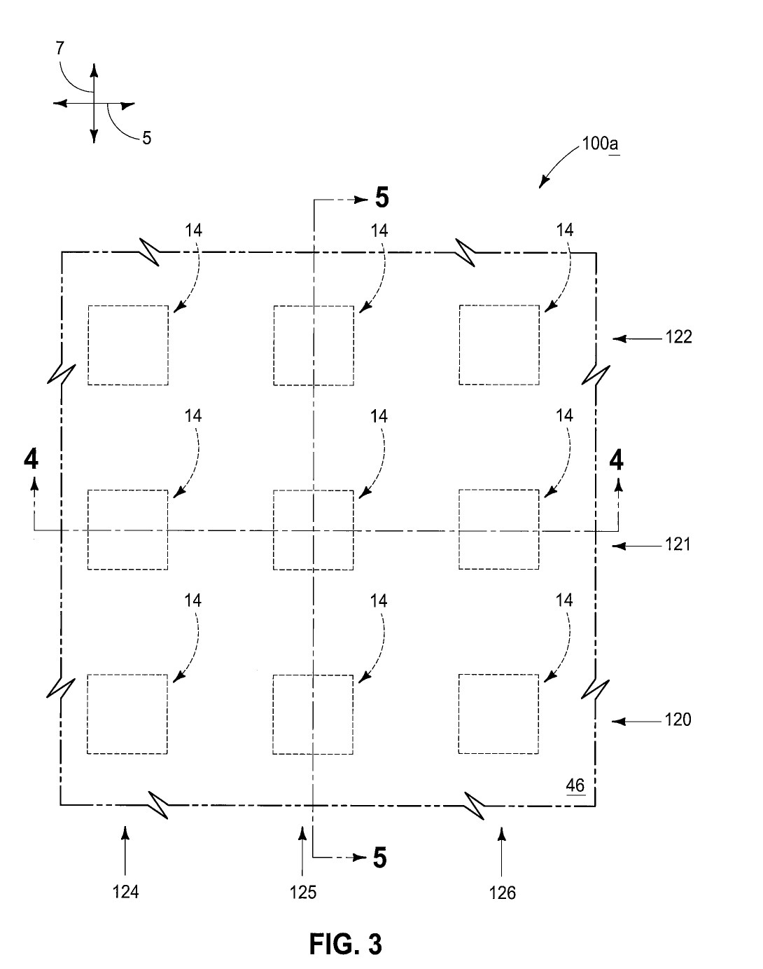

FIGS. 3-6 illustrate an example embodiment memory array 100a analogous to the memory array 100, but illustrate such memory from the perspective of a top view and two cross-sectional views, rather than from the perspective of a three-dimensional view.

The top view of FIG. 3 shows the conductive material 46 extending across a plurality of memory structures 14. The memory structures are shown in phantom view to indicate that such memory structures are beneath the conductive material 46. The memory structures are arranged in an array comprising rows 120-122 and columns 124-126. The rows extend along axis 5 and the columns extend along axis 7.

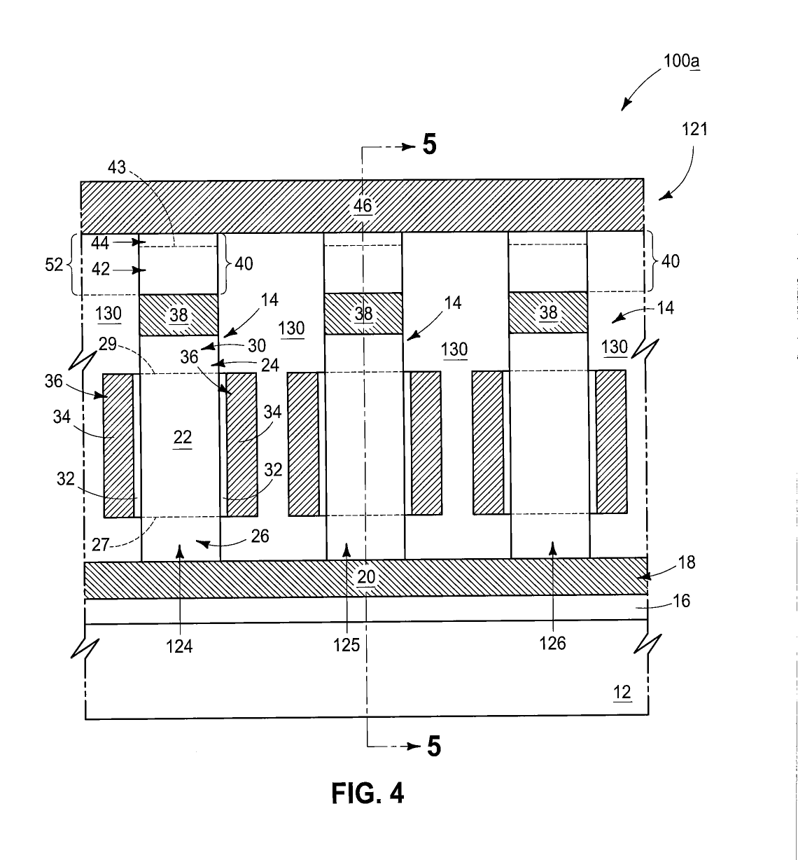

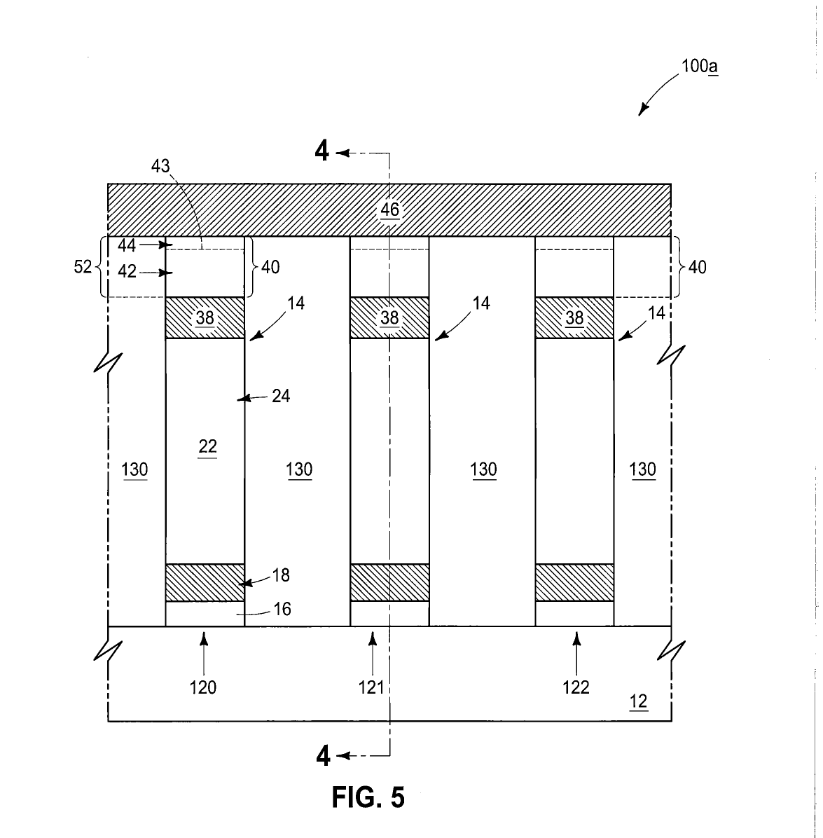

The view of FIG. 4 is along the center of row 121, and the view of FIG. 5 is along the center of column 125. Electrically insulative material 130 (shown in FIGS. 4 and 5) is provided between adjacent memory cell structures 14 to electrical isolate such memory cell structures from one another. The electrically insulative material 130 may comprise any suitable electrically insulative composition or combination of compositions; and in some embodiments may comprise, consist essentially of or consist of one or more of silicon dioxide, silicon nitride, and any of various doped silicate glasses (for instance, borophosphosilicate glass, phosphosilicate glass, fluorosilicate glass, etc.).

The embodiment of FIGS. 3-5 shows programmable material 40 patterned into individual structures having common lateral dimensions as the underlying pedestals 24 of semiconductor material 22. Such programmable material structures may be formed by utilizing a common mask to pattern the programmable material 40 and the underlying semiconductor material 22. The programmable material 40 of FIGS. 3-5 may be considered to be patterned into structures that are in one-to-one correspondence with the vertical transistors.

FIGS. 6-8 illustrate a memory array 100b, and show another example embodiment. Identical numbering will be utilized to describe the embodiment of FIGS. 6-8 as is utilized above in describing the embodiment of FIGS. 3-5, where appropriate.

The top view of FIG. 6 shows the conductive material 46 extending across a plurality of memory structures 14. The memory structures are shown in phantom view to indicate that such memory structures are beneath the conductive material 46. The memory structures are arranged in an array comprising rows 120-122 and columns 124-126. The rows extend along axis 5 and the columns extend along axis 7.

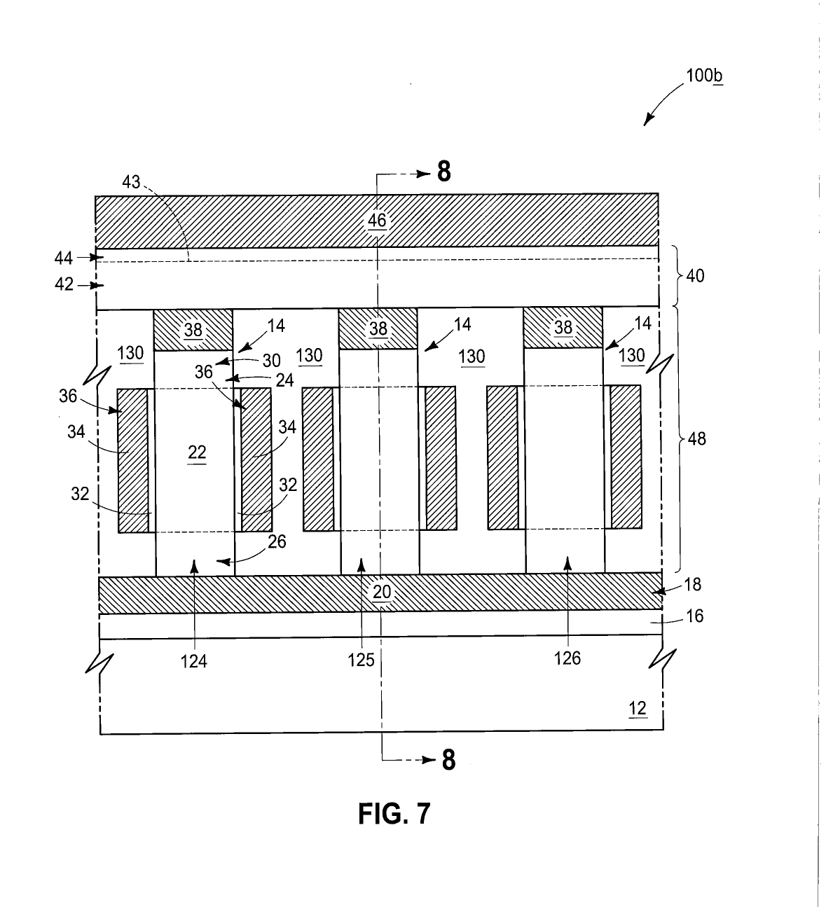

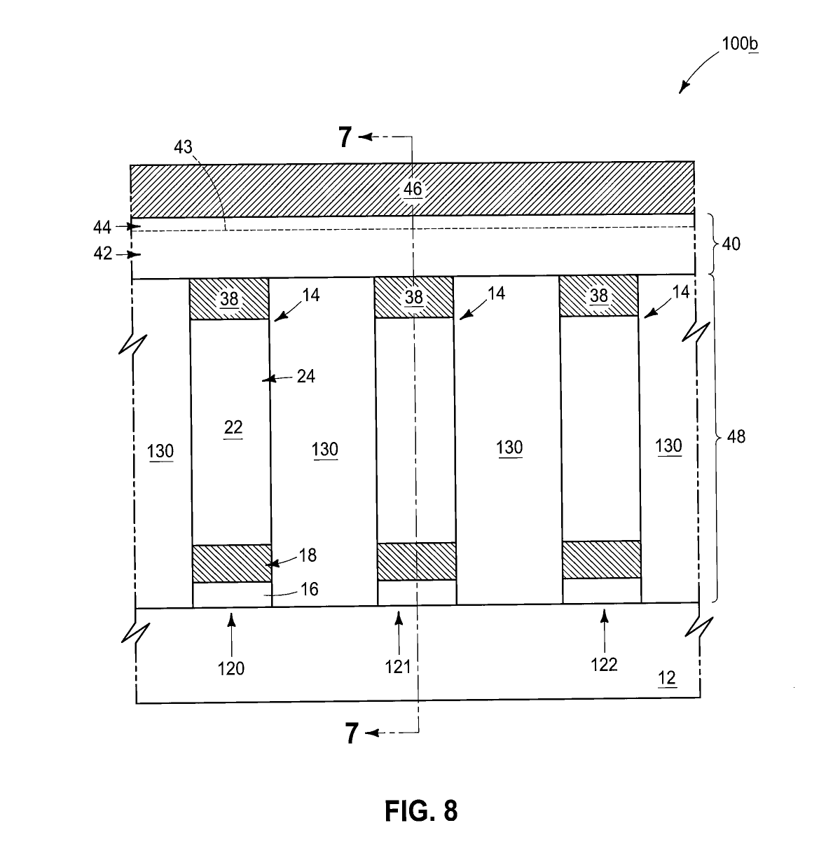

The cross-sectional views of FIGS. 7 and 8 show that programmable material 40 is a continuous expanse extending across all of the vertical transistors 48.

The memory structures and arrays discussed above may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, clocks, televisions, cell phones, personal computers, automobiles, industrial control systems, aircraft, etc.

The particular orientation of the various embodiments in the drawings is for illustrative purposes only, and the embodiments may be rotated relative to the shown orientations in some applications. The description provided herein, and the claims that follow, pertain to any structures that have the described relationships between various features, regardless of whether the structures are in the particular orientation of the drawings, or are rotated relative to such orientation.

The cross-sectional views of the accompanying illustrations only show features within the planes of the cross-sections, and do not show materials behind the planes of the cross-sections in order to simplify the drawings.

When a structure is referred to above as being “on” or “against” another structure, it can be directly on the other structure or intervening structures may also be present. In contrast, when a structure is referred to as being “directly on” or “directly against” another structure, there are no intervening structures present. When a structure is referred to as being “connected” or “coupled” to another structure, it can be directly connected or coupled to the other structure, or intervening structures may be present. In contrast, when a structure is referred to as being “directly connected” or “directly coupled” to another structure, there are no intervening structures present.

Some embodiments include a memory cell structure. The structure comprises a vertical transistor having a bottom source/drain region electrically coupled to a first access/sense line, and having a gate comprised by a second access/sense line. The structure also comprises programmable material over the vertical transistor and electrically coupled with a top source/drain region of the vertical transistor, with the programmable material comprising at least two compositionally different regions. The structure also comprises an electrically conductive material over and directly against the programmable material.

Some embodiments include a memory array. The memory array comprises a first series of access/sense lines extending along a first direction, and a second series of access/sense lines extending along a second direction that intersects the first direction. The memory array also comprises a plurality of vertical transistors. Individual vertical transistors comprise a channel region that interconnects a top source/drain with a bottom source/drain region. The access/sense lines of the second series include gates of the vertical transistors, and the access/sense lines of the first series are electrically coupled with the bottom source/drain regions of the vertical transistors. The memory array also comprises programmable material over the vertical transistors and electrically coupled with the top source/drain regions. The programmable material is incorporated into a plurality of data-retaining cells, with individual data-retaining cells being over individual vertical transistors. The programmable material comprises at least two compositionally different regions. The memory array also comprises an electrically conductive material extending across at least two adjacent data-retaining cells.

Some embodiments include a memory array. The memory array comprises a first series of access/sense lines extending along a first direction, and a second series of access/sense lines extending along a second direction that intersects the first direction. The memory array also comprises a plurality of vertical transistors. Individual vertical transistors comprise a channel region that interconnects a top source/drain with a bottom source/drain region. The access/sense lines of the second series include gates of the vertical transistors, and the access/sense lines of the first series are electrically coupled with the bottom source/drain regions of the vertical transistors. The memory array also comprises programmable material over the vertical transistors and electrically coupled with the top source/drain regions. The programmable material is incorporated into a plurality of data-retaining cells, with individual data-retaining cells being over individual vertical transistors. The programmable material comprises at least two compositionally different regions. The memory array also comprises at least one electrically conductive structure over and directly against the programmable material. The first series of access/sense lines forms rows of the memory array, and the second series of access/sense lines forms columns of the memory array. The electrically conductive structure extends across two or more adjacent data-retaining cells along a row, and extends across two or more adjacent data-retaining cells along a column.

Some embodiments include a memory array. The memory array comprises a first series of access/sense lines extending along a first direction, and a second series of access/sense lines extending along a second direction that intersects the first direction. The memory array also comprises a plurality of vertical transistors. Individual vertical transistors comprise a channel region that interconnects a top source/drain with a bottom source/drain region. The access/sense lines of the second series include gates of the vertical transistors, and the access/sense lines of the first series are electrically coupled with the bottom source/drain regions of the vertical transistors. The memory array also comprises programmable material over the vertical transistors and electrically coupled with the top source/drain regions. The programmable material comprises multivalent metal oxide. The memory array also comprises an electrically conductive plate which is directly against the programmable material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1-9. (canceled)

10. A dynamic random access memory array, comprising:
a first series of access/sense lines extending along a first direction and being supported by a semiconductor substrate;
a second series of access/sense lines extending along a second direction that intersects the first direction;
a plurality of vertical transistors; individual vertical transistors comprising a channel region that interconnects a top source/drain with a bottom source/drain region; the access/sense lines of the second series including gates of the vertical transistors, and the access/sense lines of the first series being electrically coupled with the bottom source/drain regions of the vertical transistors;
programmable material over the vertical transistors and electrically coupled with the top source/drain regions; the programmable material being incorporated into a plurality of data-retaining structures, with individual data-retaining structures being over individual vertical transistors; the programmable material comprising at least two compositionally different regions with one of said regions of the programmable material comprising multivalent metal oxide containing a composition having oxygen in combination with one or more of praseodymium, barium, calcium, manganese, strontium, titanium, iron, cesium and lead;
an electrically conductive material extending across at least two adjacent data-retaining structures; and
wherein the first series of access/sense lines forms rows of the dynamic random access memory array, and the second series of access/sense lines forms columns of the dynamic random access memory array; and wherein the electrically conductive material extends across and in direct electrical contact with two or more adjacent data-retaining structures along a row, and extends across and in direct electrical contact with two or more adjacent data-retaining structures along a column.

11. The dynamic random access memory array of claim 10 wherein the electrically conductive material extends across all of the data-retaining structures of the memory array.

12. A dynamic random access memory array, comprising:
a first series of access/sense lines extending along a first direction;
a second series of access/sense lines extending along a second direction that intersects the first direction;
a plurality of vertical transistors; individual vertical transistors comprising a channel region that interconnects a top source/drain with a bottom source/drain region; the access/sense lines of the second series including gates of the vertical transistors, and the access/sense lines of the first series being electrically coupled with the bottom source/drain regions of the vertical transistors;
programmable material over the vertical transistors and electrically coupled with the top source/drain regions; the programmable material being incorporated into a plurality of data-retaining structures, with individual data-retaining structures being over individual vertical transistors; the programmable material comprising at least two compositionally different regions;
at least one electrically conductive structure over and directly against the programmable material; and
wherein the first series of access/sense lines forms rows of the memory array, and the second series of access/sense lines forms columns of the memory array; and wherein the electrically conductive structure extends across and in direct electrical contact with two or more adjacent data-retaining structures along a row, and extends across and in direct electrical contact with two or more adjacent data-retaining structures along a column.

13. The dynamic random access memory array of claim 12 wherein the electrically conductive structure extends across all of the data-retaining structures of the array.

14. The dynamic random access memory array of claim 12 wherein the electrically conductive structure is a plate of substantially uniform thickness, and is entirely over the data-retaining structures.

15. The dynamic random access memory array of claim 12 wherein the compositionally different regions of the programmable material include a multivalent metal oxide region and an electrically insulative region adjacent the multivalent metal oxide region.

16-21. (canceled)

22. The dynamic random access memory array of claim 10 wherein the programmable material comprises a lateral dimension equal to a lateral dimension of at least one of: the top source/drain region, the channel region and the bottom source/drain region.

23. The dynamic random access memory array of claim 10 wherein each region of the at least two compositionally different regions comprise the same thickness dimensions.

24. The dynamic random access memory array of claim 10 wherein the bottom source/drain region comprises a discrete structure that is separate from the structure of the first series of the access/sense lines.

25. The dynamic random access memory array of claim 10 wherein the at least two compositionally different regions comprise a first region and a second region, an entirety of the structure of the first region being elevationally below an entirety of the structure of the second region.

26. The dynamic random access memory array of claim 10 further comprising Schottky barrier material between the top source/drain and the programmable material.

27. The dynamic random access memory array of claim 12 wherein the programmable material comprises a lateral dimension equal to a lateral dimension of at least one of: the top source/drain region, the channel region and the bottom source/drain region.

28. The dynamic random access memory array of claim 12 wherein each region of the at least two compositionally different regions comprise the same thickness dimensions.

29. The dynamic random access memory array of claim 12 wherein the bottom source/drain region comprises a discrete structure that is separate from the structure of the first series of the access/sense lines.

30. The dynamic random access memory array of claim 12 wherein the at least two compositionally different regions comprise a first region and a second region, an entirety of the structure of the first region being elevationally below an entirety of the structure of the second region.

31. The dynamic random access memory array of claim 12 further comprising Schottky barrier material between the top source/drain and the programmable material.
